(19) United States
(12) Patent Application Publication
(10) Pub. No.: US 2013/0319506 A1
(43) Pub. Date: Dec. 5, 2013

(54) SOLAR CONCENTRATOR ASSEMBLY

(71) Applicant: Universiti Tunku Abdul Rahman, Selangor Darul Ehsan (MY)

(72) Inventors: Kok Keong CHONG, Kuala Lumpur (MY); Chee Woon WONG, Negeri Sembilan Darul Khusus (MY); Tiong Keat YEW, Kedah Darul Aman (MY); Ming Hui TAN, Penampang (MY)

(73) Assignee: UNIVERSITI TUNKU ABDUL RAHMAN, Selangor Darul Ehsan (MY)

(21) Appl. No.: 13/901,519

(22) Filed: May 23, 2013

(30) Foreign Application Priority Data
May 31, 2012 (MY) PI2012002439

(51) Int. Cl. H01L 31/052; F24J 2/00

(52) U.S. Cl. CPC H01L 31/0525; F24J 2/0015
USPC 136/246

(57) ABSTRACT

The present invention provides a solar concentrator assembly comprising a non-imaging dish concentrator and a photovoltaic receiver for the application of concentrator photovoltaic system that provides uniform solar flux, matches the square or rectangular solar images to the square or rectangular dimension of the photovoltaic receiver and produces high solar concentration ratio. The present invention also provides a solar concentrator assembly that is cost effective and has simpler mechanical structure.

This application claims priority under the Paris Convention from Malaysian Patent Application No. PI2012002439 filed on May 31, 2012, which is hereby expressly incorporated by reference in its entirety for all purposes.

### TECHNICAL FIELD

The present invention relates to a solar concentrator assembly, more particularly, relates to a non-imaging dish concentrator assembly for the application of concentrator photovoltaic system and other relevant applications that requires uniform concentrated flux.

### BACKGROUND OF THE INVENTION

Developing countries across the globe struggle in deriving or generating the basic necessities of life for themselves. Among the other necessities, energy supply such as electricity still remains one of the major requirements in the economies of developing nations which is unattained.

Over the years, people have largely relied on fossil fuels to meet their energy demands. However, the indiscriminate use of these non-renewable sources of energy has posed a threat of their depletion in the near future and hence the search for alternative sources of energy generation is sought. Owing to the need of the hour, tapping of renewable sources of energy such as solar energy to meet the growing demands has significantly increased.

Solar energy is available in plenty and it can be utilized by converting it to different energy forms such as thermal and electrical energy. Thus, the solar energy can be stored in different forms for use according to the need of the consumer.

Photovoltaic cells are in use that converts solar energy into electrical energy. These cells can directly operate on the sunlight falling on it directly. However, since the photovoltaic cells are relatively expensive and sensitive, it is judicious to concentrate the solar energy with the aid of concentrators which can then be targeted to the photovoltaic cells. A number of individual photovoltaic cells comprise a photovoltaic receiver that converts solar energy to electrical energy.

Various types of reflective and refractive concentrators have been devised for concentrating photovoltaic systems such as the parabolic dish concentrators, line focus concentrators and lens point focus concentrators. Of the different types of concentrators in use, in the parabolic dish concentrators, the resulting concentrated solar flux present in Gaussian distribution pattern and the receiver intercepts the Gaussian flux distribution on either side of its focal point, with the receiver surface preferably lying in a plane substantially normal to the axis.

However, the concentrated light image provided by a typical parabolic dish-shaped concentrator is either elliptic or circular, whereas the optimum receiving surface for many photovoltaic receivers is either rectangular or squared shape, which does not match with the profile of the concentrated light image. The receiver could be oversized to receive practically all of the concentrated light, but the corners of the receiver would then receive little or no concentrated light. In the lens point focus concentrators, there is no uniform solar flux and thus secondary optics is needed to make it more efficient.

To cater the problem of achieving full coverage of concentrated flux on the receiver surface, one way would be to oversize the concentrator so that the receiver surface fits completely within its image. However, a problem with this solution is that a substantial amount of concentrated flux may miss the receiver completely because the flux concentration image would necessarily have a greater area than the receiver surface. Such an energy system would therefore have a lower optical efficiency corresponding to its concentrated flux losses.

Thus, there is an unmet need for a solar concentrator assembly for the application of concentrator photovoltaic system that provides uniform solar flux, match the square or rectangular solar images to the square or rectangular dimension of the photovoltaic receiver and produce high solar concentration ratio. There is also a need in the art for a solar concentrator assembly that is cost effective and has simpler mechanical structure.

### SUMMARY OF THE INVENTION

The present invention meets the aforementioned and other needs by providing a new design of solar concentrator assembly based on the concept of non-imaging optics for the application of concentrator photovoltaic system. Since the concentrator photovoltaic system requires cooling to avoid overheating of the solar cells, the waste heat collected from the cooling water flowing through the cooling block attached to the photovoltaic receiver can also be used for additional power generation. Furthermore, the application of the new solar concentrator is not limited to concentrator photovoltaic system, but can also be extended to direct conversion of solar energy to thermal energy such as producing high pressure steam, etc.

Additional features of the invention will be set forth in the description which follows, and in part will be apparent from the description, or may be learned by practice of the invention.

In the practice of the present invention, a solar concentrator assembly is provided for a solar energy system including a non-imaging dish concentrator and a photovoltaic receiver. The non-imaging dish concentrator comprises a plurality of optical assembly sets that can be arranged into any form of array. Each of the plurality of optical assembly sets comprises four flat mirrors placed together sharing one common pivot point at the centre relative to which they are inclined to create tilted angles. The tilted angles created in the four flat mirrors superpose the resultant four images of the said four flat mirrors into one. The image formed is intended to match with the square or rectangular dimension of the concentrator photovoltaic receiver thus ensuring uniform solar flux and high solar concentration ratio.

It is to be understood that both foregoing general descriptions and the following detailed description are exemplary and explanatory and are intended to provide further explanation of the invention as claimed. Other features and aspects will be apparent from the following detailed description, the drawings, and the claims.

### BRIEF DESCRIPTION OF THE DRAWINGS

The present disclosure is described in conjunction with the appended figures, where similar components and/or features may have the same reference label:

FIG. 1 illustrates a perspective view of a solar concentrator assembly with a photovoltaic receiver according to an exemplary embodiment of the invention.

FIG. 2 illustrates a schematic diagram showing the arrangement of the plurality of optical assembly sets into a hexagonal array to form a complete non-imaging dish concentrator: Top view (top picture) and Isometric view (bottom picture).

FIG. 3 illustrates a schematic diagram showing the cross-sectional view of the non-imaging dish concentrator and how the sunrays are superposed at the photovoltaic receiver. (Dotted line X-X′ represents the cross sectional view taken from the isometric view as shown in FIG. 2).

FIG. 4 depicts a coordinate system to describe the normal of an optical assembly set with coordinate (Hₓ, H_{y}, H_{z}), where (0,0,0) is the central point of non-imaging dish concentrator and (0,0,F) is the central point of the photovoltaic receiver.

FIG. 5 illustrates the superposition of all the images of four flat component mirrors of each optical assembly set into one by inclining them with reference to a common pivot at the centre.

### DETAILED DESCRIPTION OF THE INVENTION

The present invention will now be described in detail with reference to the accompanying drawings, in which exemplary embodiments of the invention are shown. This invention may, however, be embodied in many different forms and should not be construed as limited to the embodiments set forth herein. Rather, these exemplary embodiments are provided so that this disclosure is thorough, and will fully convey the scope of the invention to those skilled in the art.

The present invention provides a solar concentrator assembly for the application of concentrator photovoltaic system. In a preferred embodiment, the present invention provides a solar concentrator assembly comprising an optically efficient, cost effective non-imaging dish concentrator.

One embodiment of the present invention provides a solar concentrator assembly comprising a non-imaging dish concentrator and a photovoltaic receiver. The non-imaging dish concentrator is specifically designed to obtain maximum optical efficiency and provide uniform irradiance on the array of solar cells at the receiver.

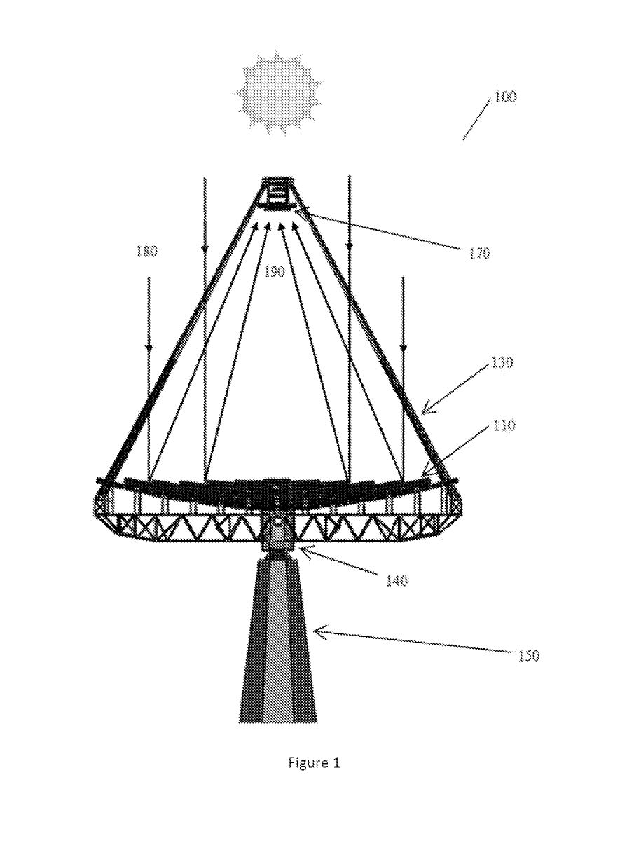

Referring to the drawings in more detail, FIG. 1 illustrates a perspective view of a solar concentrator assembly with a photovoltaic receiver according to an exemplary embodiment of the invention. Referring to FIG. 1, the solar concentrator assembly (100) of the present invention comprises a non-imaging dish concentrator (110) and a photovoltaic receiver (170). The whole structure, i.e., the solar concentrator assembly (100) is mounted on at least one pedestal (150) so that the solar concentrator assembly (100) is well supported. The non-imaging dish concentrator (110) is mounted over the at least one pedestal (150) and is properly fitted.

It is held in position with the help of at least one gearbox (140) which is flexible in operation and aids in movement of the solar concentrator assembly according to the intensity of the sunrays. The non-imaging dish concentrator (110) is held in position with the photovoltaic receiver (170) with the help of a plurality of structural support means (130). The sunrays are incident (180) on the non-imaging dish concentrator (110) which concentrates the solar energy and reflects (190) it to the photovoltaic receiver (170).

The non-imaging dish concentrator (110) further comprises a plurality of optical assembly sets (120) arranged into any form of array but in the present invention, it is preferably a hexagonal and staggered array. The plurality of optical assembly sets (120) is composed of a plurality of flat facet mirrors. Each of the plurality of optical assembly sets (120) comprises four flat mirrors placed together sharing one common pivot point (160) at the centre of optical assembly set. In a preferred embodiment of the present invention, flat facet mirrors are used which ensures uniform solar flux.

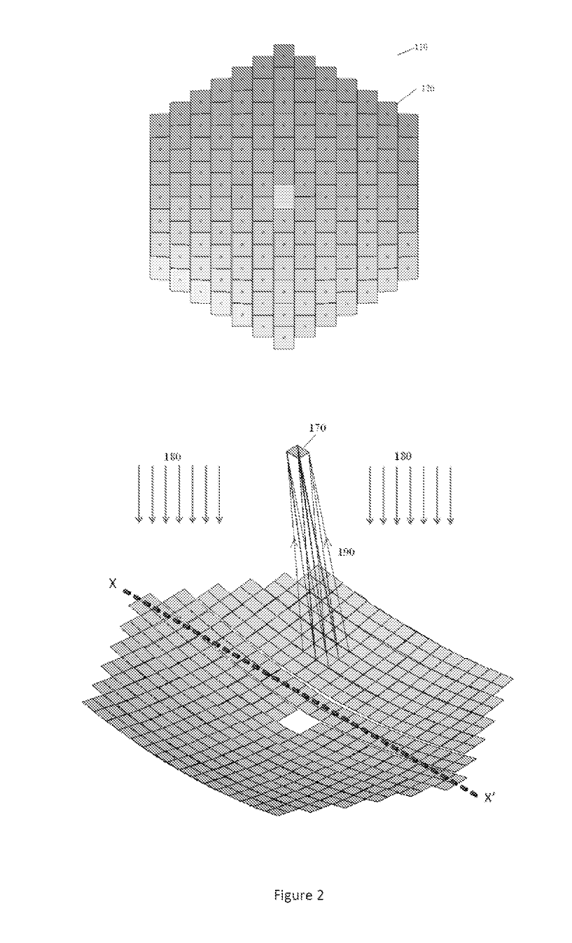

FIG. 2 illustrates a schematic diagram showing the arrangement of the plurality of optical assembly sets (120) into a hexagonal array to form a complete non-imaging dish concentrator (110). However, the non-imaging dish concentrator (110) is not limited to the design as shown in FIG. 2, which is just an exemplary illustration of one possible arrangement. In addition, the non-imaging dish concentrator (110) can also have any solar concentration ratio dependent on the applications by simply increasing or decreasing the total number of optical assembly sets (120).

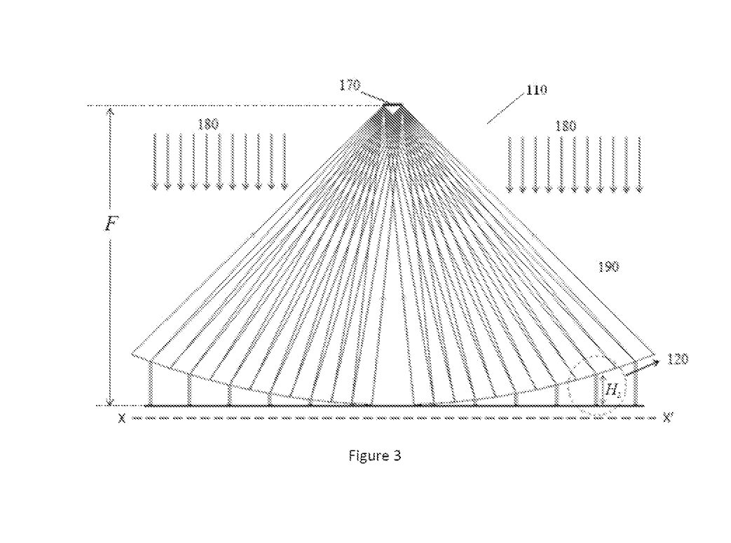

FIG. 3 illustrates a schematic diagram showing the cross-sectional view of the non-imaging dish concentrator (110). The non-imaging dish concentrator (110) superposes the solar images formed on it to the photovoltaic receiver (170). In FIG. 3, the height (H_{z}) of optical assembly sets (120) are gradually lifted from central to peripheral position of the non-imaging dish concentrator (110) to avoid shadowing and blocking between adjacent mirrors.

In an embodiment of the present invention, the total number of suns is dependent on the total number of optical assembly sets. Each optical assembly set can superpose the images of four component flat mirrors, which is equivalent to four suns. The number of optical assembly sets can be increased by adding it next to the circumference of the arrangement and the solar concentration ratio will be increased in a multiple of four suns.

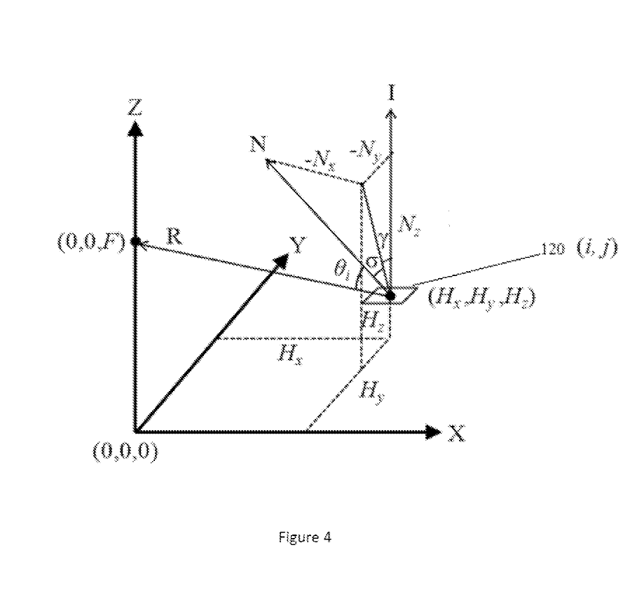

FIG. 4 depicts a coordinate system to describe the normal of a optical assembly set with coordinate (Hₓ, H_{y}, H_{z}). The focal length (F) is defined as the shortest distance between the central point of the non-imaging dish concentrator with coordinate (0,0,0) and the central point of the photovoltaic receiver with coordinate (0,0,F). In the present invention, selection of the focal length (F) of the non-imaging dish concentrator (110) is allowable in order to obtain the best solar flux distribution at the photovoltaic receiver (170). The tilted angles (σ and γ) of each optical assembly set (120) are in the function of the focal length (F) and its respective coordinate (Hₓ, H_{y}, H_{z}) so that the incident sunrays (180) fallen on the optical assembly set (120) can be reflected (190) and superposed at the photovoltaic receiver (170) as shown in FIGS. 2-3.

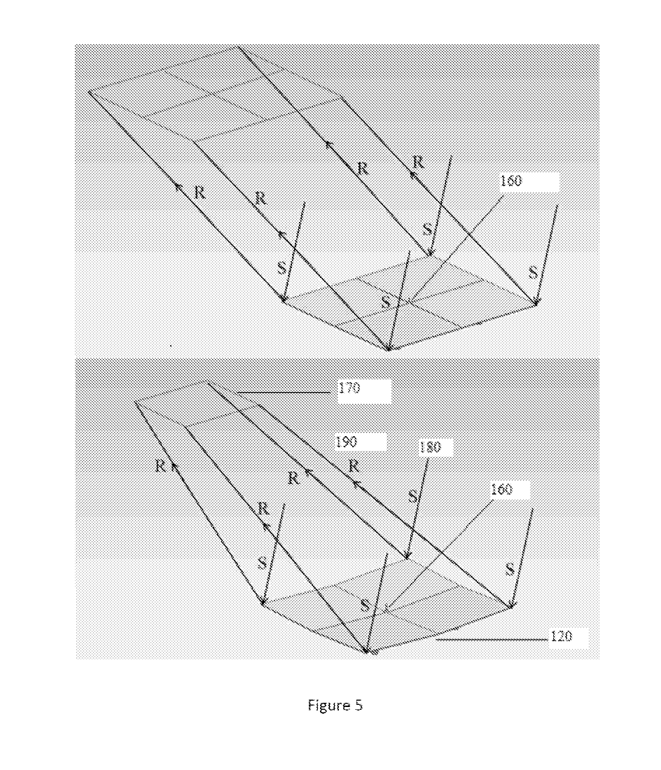

FIG. 5 illustrates the superposition of all the images of four flat component mirrors of each optical assembly set into one by inclining them relative to the pivot at the centre. As described earlier, four flat mirrors are placed together to form one optical assembly set (120) and they share one common pivot point (160) at the meeting point. The shape of each mirror is either rectangular or square dependent on the solar cells arrangement at the photovoltaic receiver (170). The mechanism of inclining the four flat mirrors arrangement with a reference to the common pivot point at the centre results in the image of four component mirrors to superpose or overlap into one.

In a preferred, non-limiting mode, the present invention provides a solar concentrator assembly for the application of concentrator photovoltaic system. The said solar concentrator assembly for the application of concentrator photovoltaic system is a cost effective device with simpler mechanical structure. The present invention can be employed in power industries as an alternative energy source for electricity generation. It can also be fixed on the rooftop of residential houses for producing electricity and hot water. It can be employed in rural areas and islands, which are far from the power grid system.

As will be readily apparent to those skilled in the art, the present invention may easily be produced in other specific forms without departing from its essential characteristics. The present embodiments is, therefore, to be considered as merely illustrative and not restrictive, the scope of the invention being indicated by the claims rather than the foregoing description, and all changes which come within therefore intended to be embraced therein.

While the principles of the disclosure have been described above in connection with specific apparatuses and methods, it is to be clearly understood that this description is made only by way of example and not as limitation on the scope of the invention.

1. A solar concentrator assembly comprising:
a non-imaging dish concentrator configuring a plurality of optical assembly sets arranged into any form of array; and
a concentrator photovoltaic receiver configured in such a manner to match with the dimension of superposed image.

2. The solar concentrator assembly of claim 1, wherein the plurality of optical assembly sets is composed of a plurality of flat facet mirrors.

3. The solar concentrator assembly of claim 2, wherein each of the plurality of optical assembly sets comprise four flat mirrors placed together sharing one common pivot point at the center of optical assembly set.

4. The solar concentrator assembly of claim 3, wherein the four flat mirrors placed together are inclined with reference to a common pivot point at the center of optical assembly set creating tilted angles in the plurality of optical assembly sets.

5. The solar concentrator assembly of claim 4, wherein the tilted angles, created in the plurality of optical assembly sets, superpose the resultant four images of the said four flat mirrors into one.

6. The solar concentrator assembly of claim 1, wherein selection of a focal length (F) of the non-imaging dish concentrator is allowable in this design in order to obtain the best solar flux distribution at the photovoltaic receiver.

7. The solar concentrator assembly of claim 6, wherein the tilted angles created in the plurality of optical assembly sets are a function of the focal length (F) and their respective coordinate (Hₓ, H_{y}, H_{z}).

8. The solar concentrator assembly of claim 5, wherein the superposed image intends to match with the dimension and shape of the said photovoltaic receiver.
